(19) United States
(12) Patent Application Publication
(10) Pub. No.: US 2024/0373718 A1
(43) Pub. Date: Nov. 7, 2024

(54) DISPLAY DEVICE

(71) Applicant: SAMSUNG DISPLAY CO., LTD., YONGIN-SI (KR)

(72) Inventors: Tae Kyung AHN, Yongin-si (KR); Sang Woo KIM, Yongin-si (KR); Hyang A PARK, Yongin-si (KR); Kwang Soo BAE, Yongin-si (KR); Soo Yeong HONG, Yongin-si (KR)

(21) Appl. No.: 18/599,404

(22) Filed: Mar. 8, 2024

(30) Foreign Application Priority Data
May 4, 2023 (KR) 10-2023-0058421

(51) Int. Cl. H10K 59/65; G09G 3/3233; H10K 59/121

(52) U.S. Cl. CPC H10K 59/65; H10K 59/1213; G09G 3/3233; G09G 2360/147

(57) ABSTRACT

A display device includes a first pixel emitting visible light, a second pixel emitting infrared light, and a photo sensor receiving light. The first pixel includes a first light emitting element, an emission control transistor forming a current movement path passing through the first light emitting element, and a first transistor controlling a first driving current flowing through the first light emitting element. The second pixel includes a second light emitting element, an eleventh transistor controlling a second driving current flowing through the second light emitting element, and a twelfth transistor electrically connected between a sensor data line and a gate electrode of the eleventh transistor. A gate electrode of the emission control transistor and a gate electrode of the twelfth transistor are electrically connected to each other.

### CROSS-REFERENCE TO RELATED APPLICATION

This U.S. patent application claims priority under 35 U.S.C. § 119 to Korean Patent Application No. 10-2023-0058421, filed on May 4, 2023, the disclosure of which is incorporated by reference in its entirety herein.

### 1. TECHNICAL FIELD

An embodiment of the disclosure relates to a display device.

### 2. DISCUSSION OF RELATED ART

A display device is used as a connection medium between a user and information. Examples of the display device include a liquid crystal display device and an organic light emitting display device. The display device may be applied to various electronic devices such as a smart phone, a digital camera, a notebook computer, a navigation system, and a smart television.

A biometric sensor for recognizing a fingerprint may be integrated into a display panel of the display device. However, a resolution of pixels in the display panel may be lowered due to the biometric sensor.

### SUMMARY

At least one object of the disclosure is to provide a display device having a biometric sensor and high resolution.

A display device according to an embodiment of the disclosure includes a first pixel configured to emit visible light, a second pixel configured to emit infrared light, and a photo sensor configured to receive light. The first pixel includes a first light emitting element, an emission control transistor forming a current movement path passing through the first light emitting element, and a first transistor controlling a first driving current flowing through the first light emitting element. The second pixel includes a second light emitting element, an eleventh transistor controlling a second driving current flowing through the second light emitting element, and a twelfth transistor electrically connected between a sensor data line and a gate electrode of the eleventh transistor. A gate electrode of the emission control transistor and a gate electrode of the twelfth transistor are electrically connected to each other.

In an embodiment, the second pixel does not include a transistor in addition to the eleventh transistor and the twelfth transistor.

The number of transistors included in the second pixel may be less than the number of transistors included in the first pixel.

An area of the second pixel may be less than or equal to half of an area of the first pixel in a plan view.

A total area occupied by the second pixel and the photo sensor may be less than or equal to an area occupied by the first pixel in a plan view.

The number of transistors included in the second pixel may be less than the number of transistors included in the photo sensor.

The second pixel and the photo sensor may be included in one pixel row extending in a first direction and may be arranged along a second direction in a plan view.

The display device may further include a processor configured to sense proximity or touch of an object using light received by the photo sensor in a state in which the second pixel emits light.

In an embodiment, the first pixel does not emit the visible light while the second pixel emits the infrared light. For example, the display device may operate in this mode to detect a touch or proximity, but not biometric information, while the display device is not presenting an image.

The first pixel may emit the visible light while the second pixel emits the infrared light. For example, the display device may operate in this mode to detect a touch or proximity, but not biometric information, while the display device is presenting an image.

The processor may sense biometric information using the light received by the photo sensor in a state in which the second pixel does not emit the infrared light and the first pixel emits the visible light, and the biometric information may include at least one of a fingerprint and blood pressure. For example, the display device may operate in this mode to detect biometric information, but not a touch or proximity, while the display device is presenting an image.

The photo sensor may include a light receiving element, a first sensor transistor controlling a current flowing through a readout line in response to a voltage of one electrode of the light receiving element, and a second sensor transistor electrically connected between the first sensor transistor and the readout line.

The first pixel may further include a second transistor electrically connected to a data line and a gate electrode of the first transistor, and a gate electrode of the second transistor and a gate electrode of the second sensor transistor may be electrically connected to each other.

The first transistor and the eleventh transistor may be disposed on a first layer, and the first light emitting element, the second light emitting element, and the light receiving element may be disposed on a second layer.

The first light emitting element may emit the visible light, and the second light emitting element may emit the infrared light.

The second light emitting element may emit the visible light, and the second pixel may further include first color conversion particles disposed on the second light emitting element for converting the visible light into the infrared light.

The first light emitting element and the second light emitting element may emit visible light of a first color, and the first pixel may further include a second color conversion particle disposed on the first light emitting element for converting the visible light of the first color into visible light of a second color.

The first pixel may further include a first color filter disposed on the first light emitting element, the second pixel may further include a second color filter disposed on the first color conversion particle, and the photo sensor may not include a color filter.

A display device according to an embodiment of the disclosure includes first pixels configured to emit visible light, a second pixel configured to emit infrared light, and a photo sensor configured to receive light. An area of the second pixel is less than an area of each of the first pixels in a plan view. The second pixel and the photo sensor are arranged along a second direction between two first pixels adjacent to each other in a first direction among the first pixels, in a plan view.

A total number of transistors included in the second pixel and the photo sensor may be less than the number of transistors included in the first pixel.

The display device according to an embodiment of the disclosure may include the second pixel emitting the infrared light, and the second pixel may include only two transistors. Therefore, the second pixel may have a minimal size, and resolution deterioration of the display device due to an additional disposition of the second pixel may be minimized.

In addition, at least two of the first pixel, the second pixel, and the photo sensor may share a scan line (or an emission control line). Therefore, the number of lines disposed in the display device may be reduced, and resolution deterioration due to the lines (for example, a relatively large number of lines) may be alleviated. Furthermore, a driver for driving the first pixel, the photo sensor, and the second pixel may be integrated, and a space for the driver may be reduced.

An effect according to embodiments is not limited by the contents exemplified above, and more various effects are included in the present specification.

### BRIEF DESCRIPTION OF THE DRAWINGS

The above and other features of the disclosure will become more apparent by describing in further detail embodiments thereof with reference to the accompanying drawings, in which:

FIG. 1 is a block diagram illustrating a display device according to an embodiment of the disclosure;

FIG. 2 is a block diagram illustrating an embodiment of the display device of FIG. 1;

FIG. 3 is a diagram illustrating an example of a disposition of backplane circuits of a display area of a display panel included in the display device of FIG. 2;

FIG. 4 is a diagram illustrating an example of the display area of the display panel included in the display device of FIG. 2;

FIG. 5 is a circuit diagram illustrating an example of a first pixel, a photo sensor, and a second pixel included in the display area of FIG. 4;

FIG. 6 is a waveform diagram illustrating an embodiment of an operation of the first pixel, the photo sensor, and the second pixel of FIG. 5;

FIG. 7 is a cross-sectional view illustrating an embodiment of the display area of FIG. 4;

FIG. 8 is a cross-sectional view illustrating an embodiment of the display area of FIG. 4;

FIG. 9 is a cross-sectional view illustrating an embodiment of the display area of FIG. 4; and

FIG. 10 is a diagram illustrating an operation for each mode of the first pixel and the second pixel of FIG. 5.

### DETAILED DESCRIPTION

The disclosure may be modified in various ways and may have various forms, and specific embodiments will be illustrated in the drawings and described in detail herein. In the following description, the singular forms also include the plural forms unless the context indicates otherwise.

Some embodiments are described in the accompanying drawings in relation to functional block, unit, and/or module. Those skilled in the art will understand that such block, unit, and/or module may be physically implemented by a logic circuit, an individual component, a microprocessor, a hard wire circuit, a memory element, a line connection, and other electronic circuits. This may be formed using a semiconductor-based manufacturing technique or other manufacturing techniques. The block, unit, and/or module implemented by a microprocessor or other similar hardware may be programmed and controlled using software to perform various functions discussed herein, and optionally may be driven by firmware and/or software. In addition, each block, unit, and/or module may be implemented by dedicated hardware, or a combination of dedicated hardware that performs some functions and a processor (for example, one or more programmed microprocessors and related circuits) that performs a function different from those of the dedicated hardware. In addition, in some embodiments, the block, unit, and/or module may be physically separated into two or more interacting individual blocks, units, and/or modules without departing from the scope of the inventive concept. In addition, in some embodiments, the block, unit and/or module may be physically combined into more complex blocks, units, and/or modules without departing from the scope of the inventive concept.

However, the disclosure is not limited to the embodiments disclosed below, and may be modified in various forms and may be implemented. In addition, each of the embodiments disclosed below may be implemented alone or in combination with at least one of other embodiments.

In the drawings, some components which are not directly related to a characteristic of the disclosure may be omitted to clearly represent the disclosure. Throughout the drawings, the same or similar components will be given by the same reference numerals and symbols as much as possible even though they are shown in different drawings, and repetitive descriptions will be omitted.

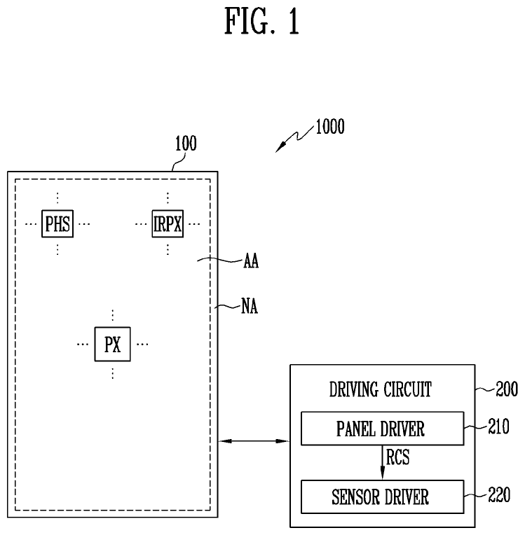

FIG. 1 is a block diagram illustrating a display device according to an embodiment of the disclosure.

Referring to FIG. 1, the display device 1000 may include a display panel 100 and a driving circuit 200. In an embodiment, the driving circuit 200 include a panel driver 210 (e.g., a first driver circuit) and a sensor driver 220 (e.g., a second driver circuit).

The display device 1000 may be implemented as a self-emission display device including a plurality of self-emission elements. In particular, the display device 1000 may be an organic light emitting display device including organic light emitting elements. However, this is an example, and the display device 1000 may be implemented as a display device including inorganic light emitting elements, a display device including light emitting elements configured of an inorganic material and an organic material in combination, a display device displaying an image using a quantum dot, or the like.

The display device 1000 may be a flat display device, a flexible display device, a curved display device, a foldable display device, a bendable display device, and a rollable display device. In addition, the display device may be applied to a transparent display device, a head-mounted display device, a wearable display device, or the like.

The display panel 100 includes a display area AA and a non-display area NA. The display area AA may be an area in which a first pixel PX is provided. The display area AA may include a plurality of pixels such as a first pixel PX. The first pixel PX may be referred to as a sub-pixel. The first pixel PX may emit light having a wavelength in a visible band (that is, visible light), and in this case, the first pixel PX may be referred to as a visible light emitting pixel. The first pixel PX may include at least one first light emitting element. For example, the first light emitting element may include a light emitting layer (for example, an organic light emitting layer). A portion of the first light emitting element emitting light may be referred to as a light emitting area. The display device 1000 may display an image in the display area AA by driving the first pixel PX in response to image data.

The non-display area NA may be an area provided around the display area AA. In an embodiment, the non-display area NA may comprehensively mean an area except for the display area AA on the display panel 100. For example, the non-display area NA may include a line area, a pad area, various dummy areas, and the like.

In an embodiment, a photo sensor PHS (or a third pixel) may be included in the display area AA. The photo sensor PHS may be referred to as a light receiving pixel or a sensor pixel. The photo sensor PHS may include a light receiving element including a light receiving layer. In the display area AA, the light receiving layer of the light receiving element may be disposed to be spaced apart from the light emitting layer of the first light emitting element.

In an embodiment, a plurality of photo sensors PHS may be distributed to be spaced apart from each other over the entire area of the display area AA. However, this is an example, and only a portion of the display area AA may be set as a predetermined sensing area, and the photo sensors PHS may be provided in the corresponding sensing area. In addition, the photo sensor PHS may be included also in at least a portion of the non-display area NA.

In embodiment, a second pixel IRPX is included in the display area AA. The second pixel IRPX emits light having a wavelength in the infrared light band (that is, infrared light). In this case, the second pixel IRPX may be referred to as an infrared light emitting pixel or an infrared emitter (IR emitter). The second pixel IRPX may include a second light emitting element including a light emitting layer. In the display area AA, the light emitting layer of the second light emitting element may be disposed to be spaced apart from the light emitting layer of the first light emitting element and the light receiving layer of the light receiving element. A plurality of second pixels IRPX may be distributed to be spaced apart from each other over the entire area of the display area AA. The second pixel IRPX may be paired with the photo sensor PHS. For example, the second pixel IRPX and the photo sensor PHS may configure one sensor unit. In this case, the second pixel IRPX may be referred to as a light emitting unit of the sensor unit, and the photo sensor PHS may be referred to as a receiving unit or sensing unit of the sensor unit.

In an embodiment, the photo sensor PHS senses that light emitted from a light source is reflected by an external object (for example, a user's finger or the like). For example, the photo sensor PHS may sense infrared light emitted from the second pixel IRPX and reflected by the user's finger, and sense proximity, touch, or the like of an object (or a user) based on the sensed infrared light. As another example, the photo sensor PHS may sense visible light emitted from the first pixel PX and reflected by the user's finger, and sense biometric information such as the user's fingerprint, iris, vein, blood pressure, and the like based on the sensed visible light.

The driving circuit 200 may include a panel driver 210 and a sensor driver 220. The display device 1000 may include the panel driver 210 and the sensor driver 220. For example, the panel driver 210 and the sensor driver 220 may be implemented as integrated circuits independent of each other, or the driving circuit 200 may be implemented as a single integrated circuit. For example, at least a portion of the sensor driver 220 may be included in the panel driver 210 or may operate in conjunction with the panel driver 210.

The panel driver 210 may scan the first pixel PX of the display area AA and supply a data signal (or a first data signal) corresponding to the image data (or an image) to the first pixel PX. The display panel 100 may display an image corresponding to the data signal.

In an embodiment, the panel driver 210 may supply a driving signal for light sensing (for example, the fingerprint sensing) to the first pixel PX. Such a driving signal may be provided so that the first pixel PX emits light to operate as a light source for the photo sensor PHS. In an embodiment, the panel driver 210 may also supply the driving signal and/or another driving signal for the light sensing to the photo sensor PHS. However, this is an example, and the driving signals for the light sensing may be provided by the sensor driver 220.

In an embodiment, the panel driver 210 may supply a driving signal for light sensing (for example, touch sensing) to the second pixel IRPX. Such a driving signal may be provided so that the second pixel IRPX emits light and operates as a light source for the photo sensor PHS. However, this is an example, and the driving signals for the light sensing may be provided from the sensor driver 220 to the second pixel IRPX.

The sensor driver 220 (or a processor) may detect touch, proximity, biometric information such as a user fingerprint, and the like, based on a sensing signal received from the photo sensor PHS. In an embodiment, the sensor driver 220 supplies the driving signals to the photo sensor PHS, the first pixel PX, and/or the second pixel IRPX.

In an embodiment, the panel driver 210 provides a readout control signal RCS to the sensor driver 220, and the sensor driver 220 reads out (or sample) the sensing signal in conjunction with the panel driver 210 based on the readout control signal RCS. For example, the sensor driver 220 may read out or sample the sensing signal in at least one pixel row (or horizontal line) unit in response to the readout control signal RCS.

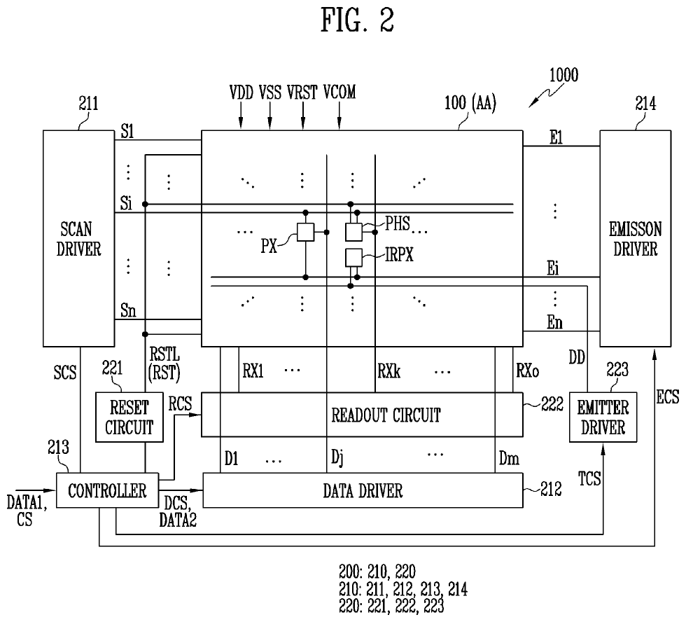

FIG. 2 is a block diagram illustrating an embodiment of the display device of FIG. 1.

Referring to FIGS. 1 and 2, the display panel 100 may include signal lines, the first pixel PX, the photo sensor PHS, and the second pixel IRPX. The signal lines may include scan lines S1 to Sn, emission control lines E1 to En, data lines D1 to Dm (or first data lines), a sensor data line DD (or a second data line), readout lines RX1 to RXo, and a reset control line RSTL (or a reset line). Here, each of n, m, and o may be a natural number.

The first pixel PX may be disposed or positioned in an area (for example, a pixel area) partitioned by the scan lines S1 to Sn (or the emission control lines E1 to En) and the data lines D1 to Dm. The photo sensor PXL and the second pixel IRPX may be disposed or positioned in an area partitioned by the scan lines S1 to Sn and the readout lines RX1 to RXo. The first pixel PX, the photo sensor PHS, and the second pixel IRPX may be arranged in a two-dimensional array in the display area AA of the display panel 100, but are not limited thereto.

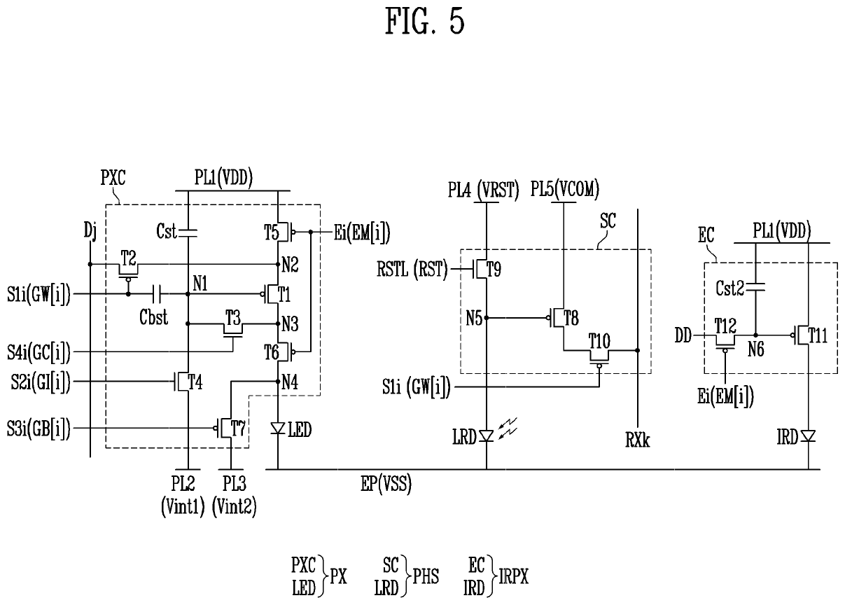

The first pixel PX may be electrically connected to at least one of the scan lines S1 to Sn, one of the emission control lines E1 to En, and one of the data lines D1 to Dm. The photo sensor PHS may be electrically connected to one of the scan lines S1 to Sn, one of the readout lines RX1) to RXo, and the reset control line RSTL. The second pixel IRPX may be electrically connected to one of the emission control lines E1 to En and the sensor data line DD. A connection configuration between the first pixel PX, the photo sensor PHS, the second pixel IRPX, and the signal lines is described later with reference to FIG. 5.

Power voltages VDD, VSS, VRST, and VCOM used to drive the first pixel PX and the photo sensor PHS may be provided to the display panel 100. The power voltages VDD, VSS, VRST, and VCOM may be provided from a power supply. The power supply may be implemented as a power management IC (PMIC).

The driving circuit 200 may include a scan driver 211 (or a gate driver), a data driver 212 (or a source driver), a controller 213 (a timing controller, a second processor, or a control circuit), an emission driver 214 (or an emission control driver), a reset circuit 221 (or a reset unit), a readout circuit 222 (or a readout unit), and an emitter driver 223. For example, the scan driver 211, the data driver 212, the controller 213, and the emission driver 214 may be included in the panel driver 210, and the reset circuit 221, the readout circuit 222, and the emitter driver 223 may be included in the sensor driver 220, but the disclosure is not limited thereto. For example, the reset circuit 221 and/or the emitter driver 223 may be included in the panel driver 210.

The scan driver 211 may be electrically connected to the first pixel PX and the photo sensor PHS through the scan lines S1 to Sn. The scan driver 211 may generate scan signals based on a scan control signal SCS (or a gate control signal), and provide the scan signals to the scan lines S1 to Sn. Here, the scan control signal SCS may include a start signal, clock signals, and the like, and may be provided from the controller 213 to the scan driver 211. For example, the scan driver 211 may be implemented as a shift register that generates and outputs the scan signals by sequentially shifting a start signal having a pulse shape using the clock signals. That is, the scan driver 211 may selectively drive the first pixel PX and the photo sensor PHS while scanning the display panel 100.

The scan driver 211 may be formed together with the first pixel PX on the display panel 100. However, the scan driver 211 is not limited thereto. For example, the scan driver 211 may be implemented as an integrated circuit.

The first pixel PX selectively driven by the scan driver 211 may emit light with a luminance corresponding to the data signal provided to the data line. For example, the first pixel PX may emit visible light. The photo sensor PHS selectively driven by the scan driver 211 may output an electrical signal (that is, the sensing signal, for example, a current/voltage) corresponding to the sensed light to the readout line. For example, the photo sensor PHS may be driven when the display panel 100 is in a mode capable of recognizing a touch input and not driven when the display panel 100 is in a different mode. For example, a first pixel PX selectively driven through an i-th scan line Si may emit light with a luminance corresponding to a data signal provided to a j-th data line Dj (where, each of i and j is a natural number). For example, the first pixel PX may be driven when the display panel 100 is being used to present an image and not driven when a user is not looking at the display panel 100. For example, a photo sensor PHS selectively driven through the i-th scan line Si may output an electrical signal corresponding to the sensed light to a k-th readout line RXk (where k is a natural number).

The data driver 212 may generate the data signal (or a data voltage) based on image data DATA2 and a data control signal DCS provided from the controller 213, and provide the data signal to the display panel 100 (or the first pixel PX) through the data lines D1 to Dm. Here, the data control signal DCS may be a signal for controlling an operation of the data driver 212, and may include a data enable signal (or a load signal) indicating an output of a valid data signal, a horizontal start signal, a data clock signal, and the like. For example, the data driver 212 may include a shift register generating a sampling signal by shifting the horizontal start signal in synchronization with the data clock signal, a latch latching the image data DATA2 in response to a sampling signal, a digital-to-analog converter (or a decoder) converting latched image data (for example, data of a digital format) into a data signal of an analog format, and a buffer (or an amplifier) outputting the data signal to the data line (for example, the j-th data line Dj).

The controller 213 may receive input image data DATA1 and a control signal CS from an external device (for example, a graphic processor, an application processor, or a first processor), generate the scan control signal SCS, the data control signal DCS, and the emission driving control signal ECS based on the control signal CS, and generate the image data DATA2 by converting the input image data DATA1. The control signal CS may include a vertical synchronization signal, a horizontal synchronization signal, a reference clock signal, and the like. The vertical synchronization signal may indicate a start of frame data (that is, data corresponding to a frame period in which one frame image is displayed), and the horizontal synchronization signal may indicate a start of a data row (that is, one data row among a plurality of data rows included in the frame data). The controller 213 may convert the input image data DATA1 into the image data DATA2 having a format matching a pixel arrangement in the display panel 100.

In addition, the controller 213 may generate a reset control signal, the readout control signal RCS, and an emitter control signal TCS based on the control signal CS.

The emission driver 214 may be electrically connected to the first pixel PX and the second pixel IRPX through the emission control lines E1 to En. The emission driver 214 may generate emission control signals based on the emission control signal ECS and provide the emission control signals to the emission control lines E1 to En. Here, the emission driving control signal ECS may include an emission start signal, emission clock signals, and the like, and may be provided from the controller 213 to the emission driver 214. For example, similar to the scan driver 211, the emission driver 214 may be implemented as a shift register. The emission driver 214 may control an emission time (or an emission duty ratio) of the first pixel PX while scanning the display panel 100. The second pixel IRPX selected by the emission driver 214 may receive a sensor data signal provided to the sensor data line DD and may emit light (or not emit light) in response to the sensor data signal. For example, the second pixel IRPX may emit infrared light or not emit infrared light.

In an embodiment, the reset circuit 221 is commonly connected to all photo sensors PHS included in the display panel 100 through one reset control line RSTL. The reset circuit 221 may simultaneously provide a reset signal RST (or the reset control signal) to all photo sensors PHS in response to the reset control signal. Here, the reset signal RST may be a control signal for providing a reset voltage VRST to the photo sensor PHS. When the reset signal RST is simultaneously provided to all photo sensors PHS, the reset signal RST may be referred to as a global reset signal.

The readout circuit 222 may receive the sensing signal from the photo sensor PHS through the readout lines RX1 to RXo and perform signal processing on the sensing signal. For example, the readout circuit 222 may perform a correlated double sampling (CDS) operation for removing noise from the sensing signal provided from the photo sensor PHS. The readout circuit 222 may perform the CDS operation in response to the readout control signal RCS. In addition, the readout circuit 222 may convert a sensing signal in an analog format into a signal in a digital format (or a digital value). A configuration for the CDS and analog-to-digital conversion may be provided for each of the readout lines RX1 to RXo, and the readout circuit 222 may process the sensing signals, which are provided from the readout lines RX1 to RXo, in parallel.

The processed sensing signals, that is, the readout sensing signals may be provided to the controller 213 as one sensing data (or biometric information), and the controller 213 may perform proximity, touch, biometric authentication, and the like. Alternatively, the readout sensing signals may be provided to an external device (for example, an application processor), and biometric authentication (for example, fingerprint authentication) may be performed based on the sensing data in the external device.

The emitter driver 223 may be connected to the second pixel IRPX through the sensor data line DD. The emitter driver 223 may provide the sensor data signal (or a second data signal) to the second pixel IRPX in response to the emitter control signal TCS. Here, the emitter control signal TCS may be a control signal for providing the sensor data signal to the second pixel IRPX. The second pixel IRPX may emit light with a luminance corresponding to the sensor data

signal provided to the sensor data line DD. For example, a second pixel IRPX selected through an i-th emission control line Ei may emit light with a luminance corresponding to the sensor data signal while the emission control signal is provided to the i-th emission control line Ei. For reference, the second pixel IRPX does not express a grayscale and may only be turned on or off for light sensing. In consideration of this, the sensor data signal may have only a specific value corresponding to an emission state or a non-emission state.

In an embodiment, the sensor data line DD is arranged similar to the reset control line RSTL, and the emitter driver 223 may be commonly connected to all second pixels IRPX. In another embodiment, the sensor data line DD is arranged similar to the data lines D1 to Dm or the readout lines RX1 to RXo, and the emitter driver 223 may be commonly connected to the second pixel IRPX included in one column. In another embodiment, the sensor data lines DD are arranged similar to the scan lines S1 to Sn or the emission control lines E1 to En, and the emitter driver 223 may be commonly connected to the second pixel IRPX included in one row. That is, an arrangement of the sensor data lines DD may be variously changed.

In FIG. 2, the emitter driver 223 is independent, but is not limited thereto. For example, the emitter driver 223 may be included in the reset circuit 221 or the readout circuit 222. As another example, the emitter driver 223 may be included in the data driver 212.

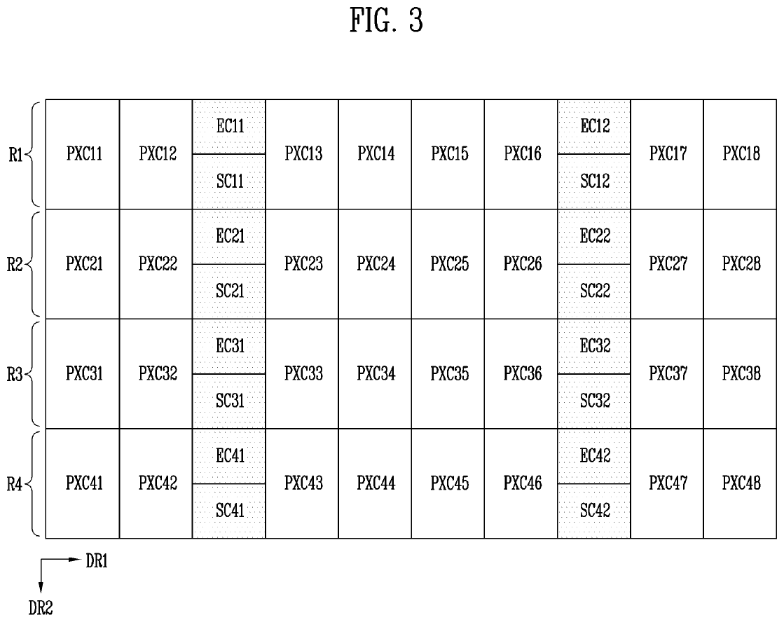

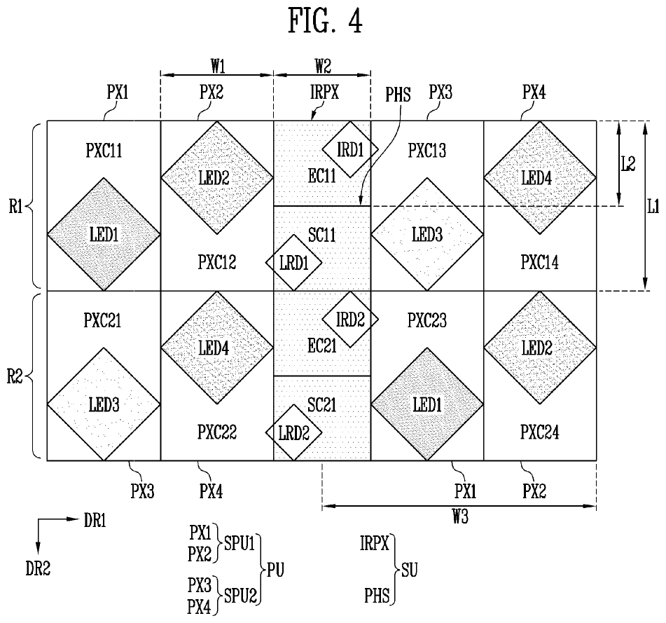

FIG. 3 is a diagram illustrating an example of a disposition of backplane circuits of the display area of the display panel included in the display device of FIG. 2. FIG. 4 is a diagram illustrating an example of the display area of the display panel included in the display device of FIG. 2.

Referring to FIGS. 1 to 4, first pixels PX1 to PX4, photo sensors PHS, and second pixels IRPX may be disposed in the display area AA of the display panel 100.

The display area AA may be divided into pixel rows R1 to R4. Each of the pixel rows R1 to R4 may extend in a first direction DR1 and may be arranged in a second direction DR2. Each of the pixel rows R1 to R4 may include the first pixels PX1 to PX4. Each of the first pixels PX1 to PX4 may include one of pixel circuits PXC11 to PXC48 (or first pixel circuits) and one of first light emitting elements LED1 to LED4. For example, pixel circuits PXC11-PXC18 may be present in the first pixel row R1, pixel circuits PXC21-PXC28 may be present in the second pixel row R2, pixel circuits PXC31-PXC38 may be present in the third pixel row R3, and pixel circuits PXC41-PXC48 may be present in the fourth pixel row R4.

In an embodiment, an eleventh pixel PX1 (or a first sub-pixel), a twelfth pixel PX2 (or a second sub-pixel), and a thirteenth pixel PX3 (or a third sub-pixel) emit first color light, second color light, and third color light, respectively. The first color light, the second color light, and the third color light may be different color light, and each of the first color light, the second color light, and the third color light may be one of red, green, and blue. In an embodiment, a fourteenth pixel PX4 (or a fourth sub-pixel) emits the same color light as the twelfth pixel PX2. For example, an eleventh light emitting element LED1 may emit the first color light, a twelfth light emitting element LED2 and a fourteenth light emitting element LED4 may emit the second color light, and a thirteenth light emitting element LED3 may emit the third light.

In FIG. 4, each of the first light emitting elements LED1 to LED4 may be understood as an emission area corresponding to the light emitting layer. However, this is merely for convenience of description, and a color of light emitted from each of the first light emitting elements LED1 to LED4, and a position, an area, a shape, and the like of each of the first light emitting elements LED1 to LED4 are not limited thereto.

In an embodiment, the first pixels PX1 to PX4 are arranged in the first direction DR1 in an order of the eleventh pixel PX1 emitting red light, the twelfth pixel PX2 emitting green light, the thirteenth pixel PX3 emitting blue light, and the fourteenth pixel PX4 emitting green light in each of odd-numbered pixel rows including a first pixel row R1 (or a first horizontal line) and a third pixel row R3 (or a third horizontal line).

The first pixels PX1 to PX4 may be arranged in the first direction DR1 in an order of the thirteenth pixel PX3, the fourteenth pixel PX4, the eleventh pixel PX1, and the twelfth pixel PX2 in each of even-numbered pixel rows including a second pixel row R2 (or a second horizontal line) and a fourth pixel row R4 (or a fourth horizontal line).

In an embodiment, the eleventh pixel PX1 and the twelfth pixel PX2 configure a first sub-pixel unit SPU1, and the thirteenth pixel PX3 and the fourteenth pixel PX4 configure a second sub-pixel unit SPU2. Therefore, the first sub-pixel unit SPU1 and the second sub-pixel unit SPU2 may be alternately disposed in odd-numbered pixel rows R1 and R3, and the second sub-pixel unit SPU2 and the first sub-pixel unit SPU1 may be alternately disposed in even-numbered pixel rows R2 and R4 in a pattern opposite to that of the odd-numbered pixel rows R1 and R3.

It may be understood that predetermined first and second sub-pixel units SPU1 and SPU2 adjacent to each other configures one pixel unit PU. For example, FIG. 4 shows a pixel unit PU in each of the first pixel row R1 and the second pixel row R2. However, this is an example, and an arrangement of the pixels is not limited thereto.

In the first pixel row R1, pixel circuits PXC11 to PXC18 corresponding to each of the first pixels PX1 to PX4 of the first pixel row R1 may be arranged in the first direction DR1. In the second pixel row R2, pixel circuits PXC21 to PXC28 corresponding to each of the first pixels PX1 to PX4 of the second pixel row R2 may be arranged in the first direction DR1. Similarly, in the third and fourth pixel rows R3 and R4, pixel circuits PXC31 to PXC38 and PXC41 to PXC48 corresponding to each of the first pixels PX1 to PX4 of the third and fourth pixel rows R3 and R4 may be arranged in the first direction DR1.

In FIG. 3, first, second, third, and fourth pixel circuits PXC11, PXC12, PXC13, and PXC14 of the first pixel row R1 may be included in one pixel unit PU, and fifth, sixth, seventh, and eighth pixel circuits PXC15, PXC16, PXC17, and PXC18 of the pixel row R1 may be included in another pixel unit PU.

Similarly to this, first to fourth pixel circuits PXC21 to PXC24 of the second pixel row R2, fifth to eighth pixel circuits PXC25 to PXC28 of the second pixel row R2, first to fourth pixel circuits PXC31 to PXC34 of the third pixel row R3, fifth to eighth pixel circuits PXC35 to PXC38 of the third pixel row R3, first to fourth pixel circuits PXC41 to PXC44 of the fourth pixel row R4, and fifth to eighth pixel circuits PXC45 to PXC48 of the fourth pixel row R4 may also be included in different pixel units PU.

In an embodiment, each of the pixel rows R1 to R4 may include light receiving elements LRD1 and LRD2. In FIG. 4, each of the light receiving elements LRD1 and LRD2 may be understood as a light receiving area corresponding to a light receiving layer. However, this is merely for convenience of description, and a position, an area, a shape, and the like of the light receiving elements LRD1 and LRD2 are not limited thereto.

A first light receiving element LRD1 of the first pixel row R1 may overlap at least a portion of each of sensor circuits SC11 and SC12 of the first pixel row R1. For example, the first light receiving element LRD1 may overlap at least a portion of a first sensor circuit SC11 of the first pixel row R1. The first light receiving element LRD1 of the first pixel row R1 may partially overlap a portion of the pixel circuits PXC11 to PXC14 of the first pixel row R1. For example, the first light receiving element LRD1 may partially overlap pixel circuit PXC12.

A second light receiving element LRD2 of the second pixel row R2 may overlap at least a portion of each of sensor circuits SC21 and SC22 of the second pixel row R2. For example, the second light receiving element LRD2 may overlap at least a portion of a first sensor circuit SC21 of the second pixel row R2. The second light receiving element LRD2 of the second pixel row R2 may partially overlap a portion of the pixel circuits PXC21 to PXC24 of the second pixel row R2. For example, the second light receiving element LRD2 may partially overlap pixel circuit PXC22.

In an embodiment, sensor circuits SC11 to SC42 may be connected to corresponding light receiving elements. For example, a first sensor circuit SC11 of the first pixel row R1 may be connected to the first light receiving element LRD1, and the first sensor circuit SC11 and the first light receiving element LRD1 may configure one photo sensor PHS. Similarly, a first sensor circuit SC21 of the second pixel row R2 may be connected to the second light receiving element

LRD2. However, the disclosure is not limited thereto. For example, only a portion of the sensor circuits SC11 to SC42 may be provided, and the portion may be connected to a plurality of light receiving elements.

The first sensor circuit SC11 of the first pixel row R1 may be disposed between the first sub-pixel unit SPU1 and the second sub-pixel unit SPU2 included in the pixel unit PU. For example, the first and second pixel circuits PXC11 and PXC12 of the first pixel row R1 may be included in the first sub-pixel unit SPU1, and the third and fourth pixel circuits PXC13 and PXC14 of the first pixel row R1 may be included in the second sub-pixel unit SPU2. Therefore, at least two pixel circuits may be disposed between the first sensor circuit SC11 and the second sensor circuit SC12 adjacent to each other in the first pixel row R1.

Similar to the first sensor circuit SC11 of the first pixel row R1, the first sensor circuit SC21 of the second pixel row R2 may be disposed between the first sub-pixel unit SPU1 and the second sub-pixel unit SPU2.

In an embodiment, each of the pixel rows R1 to R4 may include second light emitting elements IRD1 and IRD2. In FIG. 4, each of the second light emitting elements IRD1 and IRD2 may be understood as a light receiving area corresponding to the light emitting layer. However, this is merely for convenience of description, and a location, an area, a shape, and the like of the second light emitting elements IRD1 and IRD2 are not limited thereto.

A twenty-first light emitting element IRD1 of the first pixel row R1 may overlap at least a portion of emitter circuits EC11 and EC12 (or the second pixel circuits) of the first pixel row R1. For example, the twenty-first light emitting element IRD1 may overlap at least a portion of a first emitter circuit EC11 of the first pixel row R1. The twenty-first light emitting element IRD1 may partially overlap a portion of the pixel circuits PXC11 to PXC14 of the first pixel row R1. For example, the twenty-first light emitting element IRD1 may partially overlap pixel circuit PXC13.

A twenty-second light emitting element IRD2 of the second pixel row R2 may overlap at least a portion of emitter circuits EC21 and EC22 of the second pixel row R2. For example, the twenty-second light emitting element IRD2 may overlap at least a portion of a first emitter circuit EC21 of the second pixel row R2. The twenty-second light emitting element IRD2 may partially overlap a portion of the pixel circuits PXC21 to PXC24 of the second pixel row R2. For example, the twenty-second light emitting element IRD2 may partially overlap pixel circuit PXC23.

In an embodiment, emitter circuits EC11 to EC42 may be connected to corresponding light receiving elements. For example, a first emitter circuit EC11 of the first pixel row R1 may be connected to the twenty-first light emitting element IRD1, and the first emitter circuit EC11 and the twenty-first light emitting element IRD1 may configure one second pixel IRPX. Similarly, a first emitter circuit EC21 of the second pixel row R2 may be connected to the twenty-second light emitting element IRD2. However, the disclosure is not limited thereto. For example, only a portion of the emitter circuits EC11 to EC42 may be provided, and the portion may be connected to a plurality of second light emitting elements.

The first emitter circuit EC11 of the first pixel row R1 may be disposed between the first sub-pixel unit SPU1 and the second sub-pixel unit SPU2 included in the pixel unit PU. The first emitter circuit EC11 and the first sensor circuit SC11 of the first pixel row R1 may be disposed between the first sub-pixel unit SPU1 and the second sub-pixel unit SPU2 (or between two pixels adjacent in the first direction DR1). The first emitter circuit EC11 and the first sensor circuit SC11 of the first pixel row R1 may be arranged along the second direction DR2.

Similar to the first emitter circuit EC11 of the first pixel row R1, the first emitter circuit EC21 of the second pixel row R2 may be disposed between the first sub-pixel unit SPU1 and the second sub-pixel unit SPU2.

It can be understood that a pair of the photo sensor PHS and the second pixel IRPX disposed between the first sub-pixel unit SPU1 and the second sub-pixel unit SPU2 configure one sensor unit SU.

In an embodiment, in a plan view, a size (or an area) of each of the emitter circuits EC11 to EC42 is less than a size (or an area) of each of the pixel circuits PXC11 to PXC48. For example, the size of each of the emitter circuits EC11 to EC42 may be less than or equal to half of the size of each of the pixel circuits PXC11 to PXC48. In other words, in a plan view, a size of the second pixel IRPX (or an area occupied by the second pixel IRPX) may be less than a size of the first pixel PX, and, for example, the size of the second pixel IRPX may be less than or equal to half of the size of the first pixel PX.

For example, a width W1 of the second pixel circuit PXC12 of the first pixel row R1 in the first direction DR1 may be about 20 μm, and a length L1 of the second pixel circuit PXC12 of the first pixel row R1 in the second direction DR2 may be about 50 μm. A width W2 of the first emitter circuit EC11 of the first pixel row R1 in the first direction DR1 may be about 20 μm, and a length L2 of the first emitter circuit EC11 of the first pixel row R1 in the second direction DR2 may be about 25 μm. As will be described later with reference to FIG. 5, this is because the number of components (for example, transistors) included in each of the emitter circuits EC11 to EC42 is less than the number (or half thereof) of components included in each of the pixel circuits PXC11 to PXC48.

Similar to the emitter circuits EC11 to EC42, in a plan view, a size (or an area) of each of the sensor circuits SC11 to SC42 may be less than or equal to a size (or an area) of each of the pixel circuits PXC11 to PXC48. For example, the size of each of the sensor circuits SC11 to SC42 may be less than or equal to half of the size of each of the pixel circuits PXC11 to PXC48. The size of each of the sensor circuits SC11 to SC42 may be the same as that of each of the emitter circuits EC11 to EC42, but is not limited thereto.

In an embodiment, in a plan view, a total size (or a total area) of one of the emitter circuits EC11 to EC42 and one of the sensor circuits SC11 to SC42 may be less than or equal to the size (or the area) of each of the pixel circuits PXC11 to PXC48. In other words, in a plan view, a total area occupied by the second pixel IRPX and the photo sensor PHS may be less than or equal to an area occupied by the first pixel PX. As will be described later with reference to FIG. 5, this is because the total number of components (for example, transistors) included in one of the emitter circuits EC11 to EC42 and one of the sensor circuits SC11 to SC42 is less than the number (or half thereof) of components included in each of the pixel circuits PXC11 to PXC48.

In an embodiment, the first and second sub-pixel units SPU1 and SPU2 may be arranged at the same average pitch in the first direction DR1 and the second direction DR2. For example, when the length L1 of the second direction DR2 of each of the pixel circuits PXC11 to PXC48 is about 50 μm, the first and second sub-pixel units SPU1 and SPU2 may be arranged along the second direction DR2 at a pitch of about 50 μm. For example, when the width W1 of the first direction DR1 of each of the pixel circuits PXC11 to PXC48 is about 20 μm and the width W2 of the first direction DR1 of each of the emitter circuits EC11 to EC42 and the sensor circuits SC11 to SC42 is about 20 μm, the first and second sub-pixel units SPU1 and SPU2 may be arranged along the first direction DR1 at an average pitch W3 of about 50 μm.

When the size of each of the emitter circuits EC11 to EC42 (and the sensor circuits SC11 to SC42) is less than the size of each of the pixel circuits PXC11 to PXC48, resolution deterioration (that is, resolution deterioration of a display image) due to an additional disposition of the emitter circuits EC11 to EC42 (and the sensor circuits SC11 to SC42) may be alleviated or minimized.

FIG. 5 is a circuit diagram illustrating an example of the first pixel, the photo sensor, and the second pixel included in the display area of FIG. 4. In FIG. 5, for convenience of description, a first pixel PX positioned on an i-th horizontal line (or an i-th pixel row) and connected to a j-th data line Dj is shown. i-th scan lines S1i to S4i may be included in the scan lines S1 to Sn or the i-th scan line Si of FIG. 2. Hereinafter, connection may mean electrical connection, but is not limited thereto.

Referring to FIGS. 1 to 5, the first pixel PX, the photo sensor PHS, and the second pixel IRPX may be disposed on an i-th horizontal line.

The first pixel PX may include a first light emitting element LED and a pixel circuit PXC. In an embodiment, the pixel circuit PXC includes first, second, third, fourth, fifth, sixth, and seventh transistors T1, T2, T3, T4, T5, T6, and T7, a storage capacitor Cst, and a boost capacitor Cbst.

The first transistor T1 (or a driving transistor) may be connected between a first power line PL1 and a first electrode of the first light emitting element LED. The first transistor T1 may include a gate electrode connected to a first node N1. The first transistor T1 may control a current amount (or a first driving current) flowing from the first power line PL1 to an electrode EP (or a power line) through the first light emitting element LED based on a voltage of the first node N1. A first power voltage VDD may be provided to the first power line PL1, a second power voltage VSS may be provided to the electrode EP, and the first power voltage VDD may be set to be higher than the second power voltage VSS. For example, the first power voltage VDD may be about 4.6V, and the second power voltage VSS may be about −2.6V.

The second transistor T2 may be connected between the j-th data line Dj (or a first data line) and a second node N2. A gate electrode of the second transistor T2 may be connected to a 1i-th scan line S1i (or a first scan line). The second transistor T2 may be turned on when a first scan signal GW[i] (for example, a low level of first scan signal) is supplied to the 1i-th scan line S1i, to electrically connect the j-th data line Dj and the second node N2. When each of the first transistor T1 and the third transistor T3 is in a turn-on state, the second transistor T2 may be electrically connected to the first node N1, and a data signal of the j-th data line Dj may be transferred to the first node N1 in response to the first scan signal GW[i].

The third transistor T3 may be connected between the first node N1 and a third node N3. A gate electrode of the third transistor T3 may be connected to a 4i-th scan line S4i (or a third scan line). The third transistor T3 may be turned on when a fourth scan signal GC[i] is supplied to the 4i-th scan line S4i. When the third transistor T3 is turned on, the first transistor T1 may have a diode-connected shape or be diode-connected.

The fourth transistor T4 may be connected between the first node N1 and a second power line PL2. A gate electrode of the fourth transistor T4 may be connected to a 2i-th scan line S2i (or a second scan line). A first initialization power voltage Vint1 may be provided to the second power line PL2. For example, the first initialization power voltage Vint1 may be about-3.8V. The fourth transistor T4 may be turned on by a second scan signal GI[i] supplied to the 2i-th scan line S2i. When the fourth transistor T4 is turned on, the first initialization power voltage Vint1 may be supplied to the first node N1 (that is, the gate electrode of the first transistor T1).

The fifth transistor T5 (or a first emission control transistor) may be connected between the first power line PL1 and the second node N2. A gate electrode of the fifth transistor T5 may be connected to an i-th emission control line Ei. The sixth transistor T6 (or a second emission control transistor) may be connected between the third node N3 and the first light emitting element LED (or a fourth node N4). A gate electrode of the sixth transistor T6 may be connected to the i-th emission control line Ei. The fifth transistor T5 and the sixth transistor T6 may be turned on when an emission control signal EM[i] (for example, a low level of emission control signal EM[i]) is supplied to the i-th emission control line Ei. The fifth transistor T5 and the sixth transistor T6 may form a current movement path passing through the first light emitting element LED.

The seventh transistor T7 may be connected between the first electrode (that is, the fourth node N4) of the first light emitting element LED and a third power line PL3. A gate electrode of the seventh transistor T7 may be connected to a 3i-th scan line S3i. A second initialization power voltage Vint2 may be provided to the third power line PL3. For example, the second initialization power voltage Vint2 may be about −3.8V. According to an embodiment, the second initialization power voltage Vint2 may be different from the first initialization power voltage Vint1. The seventh transistor T7 may be turned on by a third scan signal GB[i] supplied to the 3i-th scan line S3i, to supply the second initialization power voltage Vint2 to the first electrode of the first light emitting element LED.

The storage capacitor Cst (or a first capacitor) may be connected or formed between the first power line PL1 and the first node N1.

The boost capacitor Cbst (or a second capacitor) may be connected or formed between the gate electrode of the second transistor T2 (or the 1i-th scan line S1i) and the gate electrode of the first transistor T1 (or the first node N1). The boost capacitor Cbst may boost the voltage of the first node N1 based on the first scan signal GW[i] supplied to the 1i-th scan line S1i. For example, the boost capacitor Cbst may more quickly transit the voltage of the first node N1 to which the data signal is transferred. According to an embodiment, the boost capacitor Cbst may be omitted.

The photo sensor PHS may include a sensor circuit SC and a light receiving element LRD. In an embodiment, the sensor circuit SC includes eighth, ninth, and tenth transistors T8, T9, and T10.

The eighth and tenth transistors T8 and T10 may be connected in series between a fifth power line PL5 and the k-th readout line RXk (where k is a natural number).

In an embodiment, the eighth transistor T8 (or a first sensor transistor) is connected between the fifth power line PL5 and the tenth transistor T10. A gate electrode of the eighth transistor T8 may be connected to a fifth node N5 (or a sensor node). The eighth transistor T8 may control a current flowing from the fifth power line PL5 to the k-th readout line RXk through the tenth transistor T10 in response to a voltage of the fifth node N5. A common voltage VCOM may be provided to the fifth power line PL5. For example, the common voltage VCOM may be about −3.8V.

According to an embodiment, the fifth power line PL5 may be electrically connected to or integrally formed with the third power line PL3, and the common voltage VCOM applied to the fifth power line PL5 may be equal to the second initialization power voltage Vint2. According to another embodiment, the fifth power line PL5 may be electrically connected to or integrally formed with the second power line PL2, and the common voltage VCOM applied to the fifth power line PL5 may be equal to the first initialization power voltage Vint1.

In an embodiment, the tenth transistor T10 (a second sensor transistor, or a switching transistor) is connected between the eighth transistor T8 and the k-th readout line RXk. A gate electrode of the tenth transistor T10 may be connected to the 1i-th scan line S1i. The gate electrode of the tenth transistor T10 may be electrically connected to the gate electrode of the second transistor T2 through the 1i-th scan line S1i. That is, the gate electrode of the tenth transistor T10 and the gate electrode of the second transistor T2 may share the 1i-th scan line S1i.

The ninth transistor T9 (or a third sensor transistor) may be connected between a fourth power line PLA (or a reference power line) and the fifth node N5. A gate electrode of the ninth transistor T9 may be connected to the reset control line RSTL. The reset voltage VRST may be provided to the fourth power line PL4, and for example, the reset voltage VRST may be about-7V.

At least one light receiving element LRD may be connected between the fifth node N5 and the electrode EP to which the second power voltage VSS is provided.

The light receiving element LRD may generate a charge (or a current) based on incident light. That is, the light receiving element LRD may perform a photoelectric conversion function. For example, the light receiving element LRD may be implemented by a photodiode.

When the ninth transistor T9 is turned on by the reset signal RST supplied to the reset control line RSTL, the reset voltage VRST may be provided to the fifth node N5. For example, the voltage of the fifth node N5 may be reset by the reset voltage VRST. After the reset voltage VRST is applied to the fifth node N5, the light receiving element LRD may perform the photoelectric conversion function.

The voltage of the fifth node N5 may be changed by an operation of the light receiving element LRD. The voltage of the fifth node N5 (or the charge or current generated in the light receiving element LRD) may be changed according to an intensity of the light incident on the light receiving element LRD and a light incident time (or a time when the light receiving element LRD is exposed to light).

When the tenth transistor T10 is turned on by the first scan signal GW[i] supplied to the 1i-th scan line S1i, a detection value (current and/or voltage) generated based on the voltage of the fifth node N5 may flow to the 1-th readout line RXk.

The second pixel IRPX may include an emitter circuit EC and a second light emitting element IRD. In an embodiment, the emitter circuit EC includes eleventh and twelfth transistors T11 and T12 and a second storage capacitor Cst2.

In an embodiment, the number of components (for example, transistors) included in the second pixel IRPX is less than the number of components (for example, transistors) included in the first pixel PX. In an embodiment, the number of components (for example, transistors) included in the second pixel IRPX is less than the number of components (for example, transistors) included in the photo sensor PHS.

The eleventh transistor T11 may be connected between the first power line PL1 and the second light emitting element IRD. A gate electrode of the eleventh transistor T11 may be connected to a sixth node N6. The eleventh transistor T11 may control a current flowing from the first power line PL1 to the electrode EP (or power line) via the second light emitting element IRD based on a voltage of the sixth node N6 (or a second driving current).

The twelfth transistor T12 may be connected between the sensor data line DD (or the second data line) and the sixth node N6. A gate electrode of the twelfth transistor T12 may be connected to the i-th emission control line Ei. The gate electrode of the twelfth transistor T12 may be electrically connected to the gate electrode of the fifth transistor T5 (and the gate electrode of the sixth transistor T6) through the i-th emission control line Ei. The twelfth transistor T12 may be turned on when the emission control signal EM[i] (for example, the low level of emission control signal EM[i]) is supplied to the i-th emission control line Ei, to electrically connect the sensor data line DD and the sixth node N6. The twelfth transistor T12 may transfer the sensor data signal to the sixth node N6 in response to the emission control signal EM[i].

The second storage capacitor Cst2 (or a third capacitor) may be connected or formed between the first power line PL1 and the sixth node N6. According to an embodiment, the second storage capacitor Cst2 may be omitted. When the second storage capacitor Cst2 is omitted, the first power line PL1 may be directly connected to the sixth node N6.

The second light emitting element IRD may emit light with a luminance corresponding to the current (or the second driving current) provided through the eleventh transistor T11.

In an embodiment, the second light emitting element IRD emits infrared light.

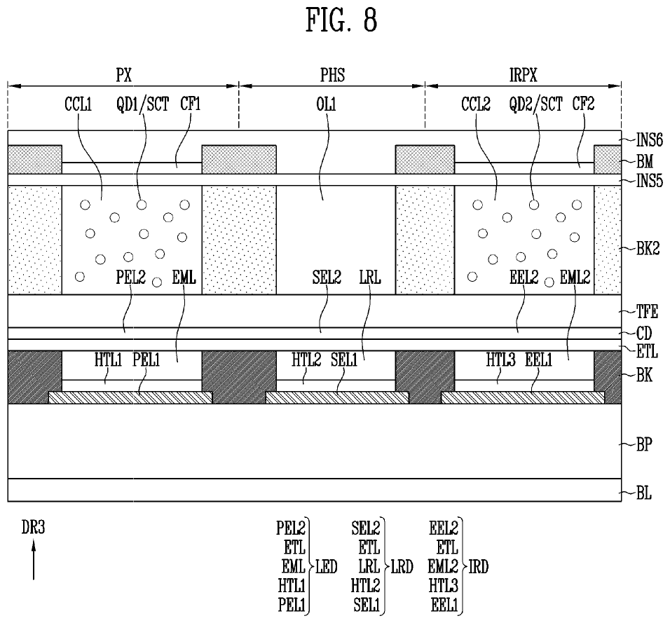

In another embodiment, the second light emitting element IRD of the second pixel IRPX is the same as the first light emitting element LED of the first pixel PX. For example, the second light emitting element IRD may emit blue light or the same type of light as the first light emitting element LED. In this case, the second pixel IRPX may convert light (for example, blue light) emitted from the second light emitting element IRD into infrared light by using a separate color conversion particle or layer and emit the infrared light to the outside (refer to FIG. 8).

In an embodiment, each of the pixel circuit PXC and the sensor circuit SC may include a P-type transistor and an N-type transistor. In an embodiment, the third transistor T3, the fourth transistor T4, and the ninth transistor T9 may be formed of an oxide semiconductor transistor including an oxide semiconductor (or a second type semiconductor). For example, the third transistor T3, the fourth transistor T4, and the ninth transistor T9 may be an N-type oxide semiconductor transistor, and may include an oxide semiconductor layer as an active layer.

The oxide semiconductor transistor may be processed at a low temperature, and has a low charge mobility compared to a polysilicon semiconductor transistor. That is, the oxide semiconductor transistor has an excellent off current characteristic. Therefore, a leakage current in the third transistor T3, the fourth transistor T4, and the ninth transistor T9 may be minimized.

The remaining transistors (for example, the first, second, fifth, sixth, seventh, eighth, tenth, eleventh, and twelfth transistors T1, T2, T5, T6, T7, T8, T10, T11, and T12)) may be formed of a polysilicon transistor including a silicon semiconductor (or a first type semiconductor), and may include a polysilicon semiconductor layer as an active layer. For example, the active layer may be formed through a low-temperature polysilicon process (for example, a low-temperature poly-silicon (LTPS) process). For example, the polysilicon transistor may be a P-type polysilicon transistor. Since the polysilicon semiconductor transistor has a fast response speed, the polysilicon semiconductor transistor may be applied to a switching element requiring fast switching.

As described above, the second pixel IRPX may include only the eleventh and twelfth transistors T11 and T12, that is, two transistors. The second pixel IRPX may not include another transistor other than the eleventh and twelfth transistors T11 and T12. For example, the second pixel IRPX does not include a transistor in addition to the eleventh and twelfth transistors T11 and T12. In this case, the second pixel IRPX may have a minimal size, and resolution deterioration due to an additional disposition of the second pixel IRPX may be minimized.

In an embodiment, as described above, the pixel circuit PXC (or the first pixel PX) and the sensor circuit SC (or the photo sensor PHS) share a scan line (for example, the 1i-th scan line S1i), and the pixel circuit PXC (or the first pixel PX) and the emitter circuit EC (or the second pixel IRPX) share the i-th emission control line Ei. In this case, the number of lines disposed on a display panel 100 (refer to FIG. 2) may be relatively reduced, and resolution deterioration due to a line (for example, a relatively large number of lines) may be alleviated. In addition, a driver (for example, the scan driver 211 and the emission driver 214) for driving the first pixel PX, the photo sensor PHS, and the second pixel IRPX may be integrated, and thus a space for the driver may be reduced.

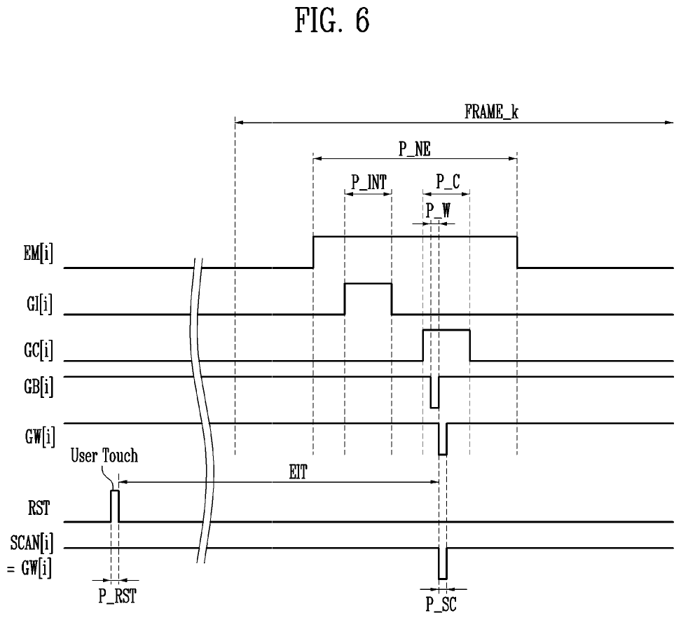

FIG. 6 is a waveform diagram illustrating an embodiment of an operation of the first pixel, the photo sensor, and the second pixel of FIG. 5.

Referring to FIGS. 1, 2, 5, and 6, the emission control signal EM[i] may be provided to the i-th emission control line Ei, the second scan signal GI[i] may be provided to the 2i-th scan line S2i, the fourth scan signal GC[i] may be provided to the 4i-th scan line S4i, the third scan signal GB[i] may be provided to the 3i-th scan line S3i, and the first scan signal GW[i] may be provided to the 1i-th scan line S1i. The reset signal RST may be provided to the reset control line RSTL. A sensing scan signal SCAN [i] (or an i-th sensing scan signal) may refer to a signal provided to the gate electrode of the tenth transistor T10. Since the gate electrode of the tenth transistor T10 is connected to the 1i-th scan line S1i, the sensing scan signal SCAN [i] may be the first scan signal GW[i].

A k-th frame period FRAME_k may include a non-emission period P_NE, and the non-emission period P_NE (or the k-th frame period FRAME_k) may include an initialization period P_INT, a compensation period P_C, and a write period P_W. The write period P_W may be included in the compensation period P_C. For example, the write period P_W may be 1 horizontal time (or horizontal period), each of the initialization period P_INT and the compensation period P_C may be 6 horizontal times, and the non-emission period P_NE may be 26 horizontal times, but the disclosure is not limited thereto. Among the k-th frame period FRAME_k, a remaining period except for the non-emission period P_NE may be an emission period, and the emission period may be greater than the non-emission period P_NE.

In the non-emission period P_NE, the emission control signal EM[i] may have a high level. In this case, the fifth transistor T5 and the sixth transistor T6 may be turned off in response to the high level of emission control signal EM[i], and the first pixel PX may not emit light. In the initialization period P_INT, the second scan signal GI[i] may have a high level.

In this case, the fourth transistor T4 may be turned on in response to the high level of second scan signal GI[i], and the first initialization power voltage Vint1 of the second power line PL2 may be provided to the first node N1 (or the gate electrode of the first transistor T1).

Thereafter, during the compensation period P_C, the fourth scan signal GC[i] may have a high level. The third transistor T3 may be turned on in response to the high level of fourth scan signal GC[i], and the first transistor T1 may be diode-connected.

In the write period P_W, the first scan signal GW[i] may have a low level. In this case, the second transistor T2 may be turned on in response to the low level of first scan signal GW[i], and the data signal may be provided to the second node N2 from the j-th data line Dj. In addition, since the third transistor T3 is turned on in response to the high level of fourth scan signal GC[i], the data signal may be transferred from the second node N2 to the first node N1 through the first transistor T1 and the third transistor T3. Since the first transistor T1 maintains the diode-connected shape by the turned-on third transistor T3, the voltage of the first node N1 may have a voltage obtained by compensating for a threshold voltage of the first transistor T1 from the data signal.

Before the write period P_W, the third scan signal GB[i] may have a low level. In this case, the seventh transistor T7 may be turned on in response to the low level of third scan signal GB[i], and the second initialization power voltage Vint2 may be supplied to the first electrode of the first light emitting element LED. The third scan signal GB[i] may be the first scan signal (for example, GW[i−1]) provided to a previous row, but is not limited thereto.

Thereafter, the non-emission period P_NE may end, and the emission control signal EM[i] may have a low level. In this case, the fifth transistor T5 and the sixth transistor T6 may be turned on in response to the low level of emission control signal EM[i], a current movement path may be formed from the first power line PL1 to the electrode EP through the fifth transistor T5, the first transistor T1, the sixth transistor T6, and the first light emitting element LED, a first driving current corresponding to the voltage (for example, the data signal) of the first node N1 may flow through the first light emitting element LED according to an operation of the first transistor T1, and the first light emitting element LED may emit light with a luminance corresponding to the first driving current.

Meanwhile, when the emission control signal EM[i] has a low level, the twelfth transistor T12 may be turned on in response to the low level of emission control signal EM[i], and the sensor data signal may be provided from the sensor data line DD to the sixth node N6. When the sensor data signal has a low level (or a voltage level turning on the eleventh transistor T11), the eleventh transistor T11 may be turned on, and the second light emitting element IRD may emit light in response to a current flowing through the eleventh transistor T11. In contrast, when the sensor data signal has a high level (or a voltage level turning off the eleventh transistor T11), the eleventh transistor T11 may be turned off, and the second light emitting element IRD does not emit light. Since the sensor data signal transferred to the sixth node N6 is stored in or maintained by the second storage capacitor Cst2, the second light emitting element IRD may maintain an emission state or a non-emission state until the sensor data signal is updated.

Meanwhile, in a reset period P_RST before the k-th frame period FRAME_k, the reset signal RST may have a high level. When a user's touch input or fingerprint sensing request is generated, the reset circuit 221 (refer to FIG. 2) may provide the high level of reset signal RST to the reset control line RSTL. The ninth transistor T9 may be turned on in response to the high level of reset signal RST, and the reset voltage VRST may be applied to the fifth node N5. The voltage of the fifth node N5 may be reset by the reset voltage VRST.

Thereafter, the ninth transistor T9 may be turned off in response to a low level of reset signal RST. When light is incident on the light receiving element LRD during an exposure time EIT, the voltage of the fifth node N5 may change due to the photoelectric conversion function of the light receiving element LRD.

In a sensing scan period P_SC of the k-th frame period FRAME_k, the sensing scan signal SCAN [i], that is, the first scan signal GW[i] may have a low level. The sensing scan period P_SC may be the same as the write period P_W. The tenth transistor T10 may be turned on in response to the first scan signal GW[i], and a current (or a detection value) may flow from the fifth power line PL5 to the k-th readout line RXk in response to the voltage of the fifth node N5.

For example, when the user's finger approaches the display panel 100 or a touch input occurs, a current corresponding to the light reflected by the user's finger, that is, the detection value, may be output in the k-th frame period FRAME_k. For example, the user's touch, fingerprint, or the like may be sensed based on the detection value.

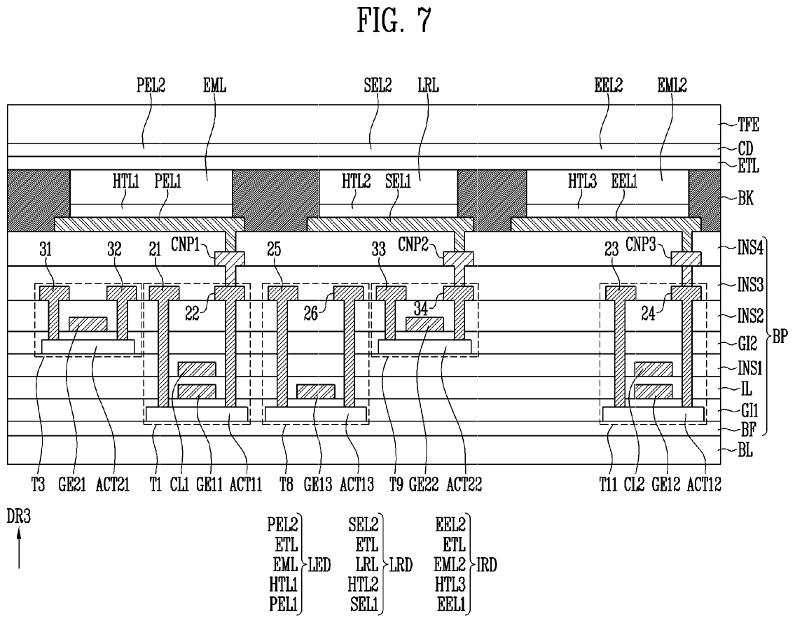

FIG. 7 is a cross-sectional view illustrating an embodiment of the display area of FIG. 4.

Referring to FIGS. 1 to 5 and 7, a base layer BL may be formed of an insulating material such as glass or resin. In addition, the base layer BL may be formed of a material having flexibility to be bent or folded, and may have a single-layer structure or a multi-layer structure. In FIG. 7, a direction perpendicular to an upper surface of the base layer BL (that is, an upper direction) is indicated as a third direction DR3.

A backplane structure BP including the pixel circuit PXC, the sensor circuit SC, and the emitter circuit EC may be formed on the base layer BL. The transistors T1 to T12 and the capacitors Cst, Cbst, and Cst2 may be included in the backplane structure BP (or a circuit layer) of the display panel 100. In FIG. 7, some of the transistors T1 to T12, for example, the first transistor T1, the third transistor T3, the eighth transistor T8, the ninth transistor T9, and the eleventh transistor T11 are shown.

The backplane structure BP may include a semiconductor layer, a plurality of conductive layers, and a plurality of insulating layers, which will be described later.

A buffer layer BF may be formed on the base layer BL. The buffer layer BF may be an insulating layer including an inorganic material. For example, the inorganic material may include at least one of metal oxides such as silicon nitride (SiNₓ), silicon oxide (SiOₓ), silicon oxynitride (SiOₓN_{y}), and aluminum oxide (AlOₓ). The buffer layer BF may prevent an impurity from diffusing into a transistor (for example, the first to twelfth transistors T1 to T12). The buffer layer BF may be omitted according to a material and a process condition of the base layer BL.

First, second, and third active patterns ACT11, ACT12, and ACT13 may be formed on the buffer layer BF. In an embodiment, the first, second, and third active patterns ACT11, ACT12, and ACT13 are formed of a polysilicon semiconductor. For example, the first, second, and third active patterns ACT11, ACT12, and ACT13 may be formed through a low-temperature polysilicon process (for example, a low-temperature poly-silicon (LTPS) process).

A first gate insulating layer GI1 may be formed on the first, second, and third active patterns ACT11, ACT12, and ACT13. The first gate insulating layer GI1 may be an inorganic insulating layer including an inorganic material. When the buffer layer BF is omitted, the first gate insulating layer GI1 may contact the base layer BL.

First, second, and third gate electrodes GE11, GE12, and GE13 may be formed on the first gate insulating layer GI1. The first gate electrode GE11 may overlap a channel area of the first active pattern ACT11, the second gate electrode GE12 may overlap a channel area of the second active pattern ACT12, and the third gate electrode GE13 may overlap a channel area of the third active pattern ACT13.

The first, second, and third gate electrodes GE11, GE12, and GE13 may include a conductive material. For example, the conductive material may include at least one of metals such as gold (Au), silver (Ag), aluminum (Al), molybdenum (Mo), chromium (Cr), titanium (Ti), nickel (Ni), neodymium (Nd), and copper (Cu), or an alloy of metals. In addition, the first, second, and third gate electrodes GE11, GE12, and GE13 may be formed as a single layer or multiple layers.

An interlayer insulating layer IL may be formed on the first, second, and third gate electrodes GE11, GE12, and GE13. The interlayer insulating layer IL may be an inorganic insulating layer including an inorganic material.

Conductive patterns CL1 and CL2 may be formed on the interlayer insulating layer IL. The conductive patterns CL1 and CL2 may form at least one of one electrode of the capacitors Cst, Cbst, and Cst2, the scan lines S1i to S4i (and the scan line SLi and the reset line RSTLi), and the j-th data line Dj (and the readout line Rxk), and the power lines PL1 to PL5. For example, a first conductive pattern CL1 overlapping the first gate electrode GE11 may form one electrode of the storage capacitor Cst. For example, a second conductive pattern CL2 overlapping the second gate electrode GE12 may form one electrode of the second storage capacitor Cst2.

The conductive patterns CL1 and CL2 may include a conductive material. In addition, the conductive patterns CL1 and CL2 may be formed as a single layer, but are not limited thereto. For example, the conductive patterns CL1 and CL2 may be formed as multiple layers in which two or more materials among metals and alloys are stacked.

A first insulating layer INS1 may be formed on the conductive patterns CL1 and CL2. The first insulating layer INS1 may be an inorganic insulating layer including an inorganic material.

A fourth active pattern ACT21 and a fifth active pattern ACT22 may be formed on the first insulating layer INS1. In an embodiment, the fourth and fifth active patterns ACT21 and ACT22 may be formed of an oxide semiconductor. For example, the fourth and fifth active patterns ACT21 and ACT22 may be formed through a metal oxide semiconductor forming process.

A second gate insulating layer GI2 may be formed on the fourth active pattern ACT21 and the fifth active pattern ACT22. The second gate insulating layer GI2 may be an inorganic insulating layer including an inorganic material.

Fourth and fifth gate electrodes GE21 and GE22 may be formed on the second gate insulating layer GI2. The fourth gate electrode GE21 may overlap a channel area of the fourth active pattern ACT21, and the fifth gate electrode GE22 may overlap a channel area of the fifth active pattern ACT22.

A second insulating layer INS2 may be formed on the fourth and fifth gate electrodes GE21 and GE22. For example, the second insulating layer INS2 may be an inorganic insulating layer including an inorganic material.

First source/drain electrodes 21 and 22, second source/drain electrodes 23 and 24, third source/drain electrodes 25 and 26, fourth source/drain electrodes 31 and 32, and fifth source/drain electrodes 33 and 34 may be formed on the second insulating layer INS2. The first to fifth source/drain electrodes 21, 22, 23, 24, 25, 26, 31, 32, 33, and 34 may be connected to the first to fifth active patterns ACT11, ACT12, ACT13, AC21, and ACT22 corresponding thereto through contact holes, respectively.

The first to fifth source/drain electrodes 21, 22, 23, 24, 25, 26, 31, 32, 33, and 34 may include a conductive material (for example, a metal).

A third insulating layer INS3 may be formed on the first to fifth source/drain electrodes 21, 22, 23, 24, 25, 26, 31, 32, 33, and 34. For example, the third insulating layer INS3 may be an inorganic insulating layer including an inorganic material.

Connection patterns CNP1, CNP2, and CNP3 may be formed on the third insulating layer INS3. For example, a first connection pattern CNP1 may be connected to the first drain electrode 22 through a contact hole passing through the third insulating layer INS3. A second connection pattern CNP2 may be connected to the fifth drain electrode 34 (or source electrode) through a contact hole passing through the third insulating layer INS3. A third connection pattern CNP3 may be connected to the second drain electrode 24 through a contact hole passing through the third insulating layer INS3.

The connection patterns CNP1, CNP2, and CNP3 may include a conductive material (for example, a metal).

A fourth insulating layer INS4 may be formed on the connection patterns CNP1, CNP2, and CNP3. The fourth insulating layer INS4 may be an insulating layer including an organic material or an inorganic material. In an embodiment, the fourth insulating layer INS4 may serve as a planarization layer.

A pixel layer including a first pixel electrode PEL1, a first sensor electrode SEL1, a third pixel electrode EEL1, and a bank layer BK may be formed on the fourth insulating layer INS4.

The pixel layer may include the first light emitting element LED connected to the pixel circuit PXC, the light receiving element LRD connected to the sensor circuit SC, and the second light emitting element IRD connected to the emitter circuit EC.

In an embodiment, the first light emitting element LED includes a first pixel electrode PEL1, a first hole transport layer HTL1, a light emitting layer EML, an electron transport layer ETL, and a second pixel electrode PEL2. In an embodiment, the light receiving element LRD includes a first sensor electrode SEL1, a second hole transport layer HTL2, a light receiving layer LRL, an electron transport layer ETL, and a second sensor electrode SEL2. In an embodiment, the second light emitting element IRD includes a third pixel electrode EEL1, a third hole transport layer HTL3, a second light emitting layer EML2, an electron transport layer ETL, and a fourth pixel electrode EEL2.

In an embodiment, each of the first pixel electrode PEL1, the first sensor electrode SEL1, and the third pixel electrode EEL1 may be formed of a metal layer of silver (Ag), magnesium (Mg), aluminum (Al), platinum (Pt), palladium (Pd), gold (Au), nickel (Ni), neodymium (Nd), iridium (Ir), chromium (Cr), an alloy thereof, or the like, indium tin oxide (ITO), indium zinc oxide (IZO), zinc oxide (ZnO), indium tin zinc oxide (ITZO), and/or the like. The first pixel electrode PEL1 may be connected to the connection pattern CNP1 through a contact hole. The first sensor electrode SEL1 may be connected to the second connection pattern CNP2 through a contact hole. The third pixel electrode EEL1 may be connected to the third connection pattern CNP3 through a contact hole.

The first pixel electrode PEL1, the first sensor electrode SEL1, and the third pixel electrode EEL1 may be simultaneously formed through patterning using a mask.

The bank layer BK (a pixel defining layer, a first bank layer, or a first bank) that partitions a light emitting area and a light receiving area may be provided on the fourth insulating layer INS4 on which first pixel electrode PEL1, the first sensor electrode SEL1, and the third pixel electrode EEL1 are formed.

The bank layer BK may be an insulating layer including an organic material. The organic material may include an acryl resin, an epoxy resin, a phenolic resin, a polyamide resin, a polyimide resin, and the like.

In addition, the bank layer BK may include a light absorbing material, or a light absorber may be applied to the bank layer BK, and thus the bank layer BK may serve to absorb light input from the outside. For example, the bank layer BK may include a carbon-based black pigment. However, the disclosure is not limited thereto, and the bank layer BK may include an opaque metal material such as chromium (Cr), molybdenum (Mo), an alloy of molybdenum and titanium (MoTi), tungsten (W), vanadium (V), niobium (Nb), tantalum (Ta), manganese (Mn), cobalt (Co), or nickel (Ni) having high light absorption.

The bank layer BK may include openings corresponding to the light emitting area and the light receiving area.

The first hole transport layer HTL1 may be formed on an upper surface of the first pixel electrode PEL1 exposed by the bank layer BK, the second hole transport layer HTL2 may be formed on an upper surface of the exposed first sensor electrode SEL1, and the third hole transport layer HTL3 may be formed on an upper surface of the exposed third pixel electrode EEL1. A hole may move to the light emitting layer EML through the first hole transport layer HTL1, a hole may move to the light receiving layer LRL through the second hole transport layer HTL2, and a hole may move to the second light emitting layer EML2 through the third hole transport layer HTL3.

In an embodiment, at least a portion of the first, second, and third hole transport layers HTL1, HTL2, and HTL3 may be the same or different according to a material of the light emitting layer EML, the light receiving layer LRL, and the second light emitting layer EML2.

The light emitting layer EML may be formed on the first hole transport layer HTL1. In an embodiment, the light emitting layer EML is formed of an organic light emitting layer. According to an organic material included in the light emitting layer EML, the light emitting layer EML may emit visible light such as red light, green light, or blue light.

In an embodiment, an electron blocking layer is formed on the second hole transport layer HTL2 in the light receiving area. The electron blocking layer may prevent a charge of the light receiving layer LRL from being moved to the hole transport layer HTL. In an embodiment, the electron blocking layer may be omitted.

The light receiving layer LRL may be formed on the second hole transport layer HTL2. The light receiving layer LRL may sense an intensity of light by emitting an electron in response to light of a specific wavelength band.

In an embodiment, the light receiving layer LRL includes a low molecular organic material. For example, the light receiving layer LRL may be formed of a phthalocyanines compound containing at least one metal selected from a group consisting of copper (Cu), iron (Fe), nickel (Ni), cobalt (Co), manganese (Mn), aluminum (Al), palladium (Pd), tin (Sn), indium (In), lead (Pb), titanium (Ti), rubidium (Rb), vanadium (V), gallium (Ga), terbium (Tb), cerium (Ce), lanthanum (La), and zinc (Zn).

Alternatively, the low molecular organic material included in the light receiving layer LRL may be configured as a bi-layer including a layer including a phthalocyanines compound containing at least one metal selected from a group consisting of copper (Cu), iron (Fe), nickel (Ni), cobalt (Co), manganese (Mn), aluminum (Al), palladium (Pd), tin (Sn), indium (In), lead (Pb), titanium (Ti), rubidium (Rb), vanadium (V), gallium (Ga), terbium (Tb), cerium (Ce), lanthanum (La), and zinc (Zn), and a layer including C60, or may be configured as a single mixing layer in which a phthalocyanines compound and C60 are mixed.

However, this is an example, and the light receiving layer LRL may include a polymer organic layer.

In an embodiment, the light receiving layer LRL may determine a light detection band of the photo sensor by controlling selection of a metal component included in the phthalocyanines compound. For example, a phthalocyanines compound containing copper absorbs a visible light wavelength of about 600 to 800 nm, and a phthalocyanines compound containing tin (Sn) absorbs a near infrared light wavelength of about 800 to 1000 nm. Therefore, by controlling the selection of the metal included in the phthalocyanines compound, a photo sensor capable of detecting a wavelength of a band desired by a user may be implemented. For example, the light receiving layer LRL may be formed to selectively absorb a wavelength of a red light band, a wavelength of a green light band, a wavelength of a blue light band, and a wavelength of an infrared light band.

In an embodiment, an area of the light receiving area is less than an area of the light emitting area.

The second light emitting layer EML2 may be formed on the third hole transport layer HTL3. In an embodiment, the second light emitting layer EML2 is configured of an organic light emitting layer. According to an organic material included in the second light emitting layer EML2, the second light emitting layer EML2 may emit infrared light or visible light such as red light, green light, or blue light.

The second pixel electrode PEL2, the second sensor electrode SEL2, and a fourth sensor electrode EEL2 may be formed on the electron transport layer ETL. In an embodiment, the second pixel electrode PEL2, the second sensor electrode SEL2, and the fourth sensor electrode EEL2 are a common electrode CD integrally formed on the display area AA. For example, a single layer may be used to form the second pixel electrode PEL2, the second sensor electrode SEL2, and the fourth sensor electrode EEL2. The second power voltage VSS may be supplied to the second pixel electrode PEL2, the second sensor electrode SEL2, and the fourth sensor electrode EEL2.

The common electrode CD may be formed of a metal layer of silver (Ag), magnesium (Mg), aluminum (Al), platinum (Pt), palladium (Pd), gold (Au), nickel (Ni), neodymium (Nd), iridium (Ir), chromium (Cr), and the like, a transparent conductive layer of ITO, IZO, ZnO, or ITZO, and/or the like. In an embodiment, the common electrode CD may be formed as multiple layers of double or more layers including a metal thin layer, for example, triple layers of ITO/Ag/ITO.

An encapsulation layer TFE (or an insulating layer) may be formed on the common electrode CD including the second pixel electrode PEL2, the second sensor electrode SEL2, and the fourth sensor electrode EEL2. The encapsulation layer TFE may be formed as a single layer, but may be formed as multiple layers. In an embodiment, the encapsulation layer TFE has a stack structure in which an inorganic material, an organic material, and an inorganic material are sequentially deposited. An uppermost layer of the encapsulation layer TFE may be formed of an inorganic material.

FIG. 8 is a cross-sectional view illustrating an embodiment of the display area of FIG. 4. Since the backplane structure BP is described with reference to FIG. 7, for convenience, the backplane structure BP is shown as one layer in FIG. 8. In other words, it should be understood that the backplane structure BP of FIG. 8 includes components (for example, the first transistor T1 and the like) of FIG. 7. In describing the embodiment of FIG. 8, a detailed description of a configuration similar to or identical to that of the previously described embodiment is omitted.

Referring to FIGS. 1 to 5, 7, and 8, color conversion layers CCL1 and CCL2 and color filters CF1 and CF2 may be disposed on the encapsulation layer TFE. In addition, a second bank layer BK2, a first organic layer OL1, a fifth insulating layer INS5, a light blocking pattern BM, and a sixth insulating layer INS6 may be further disposed on the encapsulation layer TFE.

The second bank layer BK2 (or a second bank) may be disposed on the encapsulation layer TFE. The second bank layer BK2 may overlap the bank layer BK in the third direction DR3. Similarly to the bank layer BK, the second bank layer BK2 may include openings corresponding to the light emitting area and the light receiving area. Together with the bank layer BK, the second bank layer BK2 may partition the light emitting area and the light receiving area. The second bank layer BK2 may be a structure defining a position where a color conversion layer CCL is to be supplied. The second bank layer BK2 may be an insulating layer including an organic material.

In an embodiment, the second bank layer BK2 includes a light blocking material. For example, the second bank layer BK2 may be a black matrix. According to an embodiment, the second bank layer BK2 may be configured to include at least one light blocking material and/or a reflective material to allow light emitted from the color conversion layers CCL1 and CCL2 to further proceed in the third direction DR3 (or an image display direction of the display device), thereby increasing light emitting efficiency of the color conversion layers CCL1 and CCL2 (or the first pixel PX and the second pixel IRPX).

The color conversion layers CCL1 and CCL2 (or a light conversion layer) may be disposed on the encapsulation layer TFE (or the first light emitting element LED and the second light emitting element IRD) in an area surrounded by the second bank layer BK2. A first color conversion layer CCL1 may be disposed on the first light emitting element LED, and a second color conversion layer CCL2 may be disposed on the second light emitting element IRD. In an embodiment, the color conversion layers CCL1 and CCL2 are not disposed on the light receiving element LRD, and the first organic layer OL1 may be disposed in the opening of the second bank layer BK2 on the light receiving element LRD. The first organic layer OL1 may include an organic material.

The color conversion layers CCL1 and CCL2 may include color conversion particles QD1 and QD2 (or wavelength conversion particles) corresponding to a specific color or a specific wavelength band. For example, the first color conversion layer CCL1 may include first color conversion particles QD1 that convert light of a first color (or a first wavelength band) incident from a light emitting element LD into light of a second color (a specific color, or a second wavelength band). Similarly, the second color conversion layer CCL2 may include second color conversion particles QD2 that convert light of a first color (or a first wavelength band) incident from the second light emitting element IRD into light of a third color (a specific color, or a third wavelength band).

For example, when the first pixel PX is a red pixel (or a red sub-pixel), the first color conversion layer CCL1 of the first pixel PX may include first color conversion particles QD1 that convert the light of the first color (for example, blue) emitted from the light emitting element LD into light or red. For example, when the first pixel PX is a green pixel (or a green sub-pixel), the first color conversion layer CCL1 of the first pixel PX may include first color conversion particles QD1 that convert the light of the first color (for example, blue) emitted from the light emitting element LD into light or green. For example, when the first pixel PX is a blue pixel (or a blue sub-pixel), the first color conversion layer CCL1 of the first pixel PX may include first color conversion particles QD1 that convert the light of the first color (for example, blue) emitted from the light emitting element LD into light or blue. According to an embodiment, when the first pixel PX is the blue pixel (or the blue sub-pixel) and the light emitting element LD emits blue-based light, the first pixel PX may also include a light scattering layer including light scattering particles SCT. The light scattering layer described above may be omitted according to an embodiment. According to another embodiment, when the first pixel PX is the blue pixel (or the blue sub-pixel), a transparent polymer may be provided instead of the first color conversion layer CCL1.

For example, when the second pixel IRPX is an infrared light pixel, the second color conversion layer CCL2 of the second pixel IRPX may include second color conversion particles QD2 of an infrared light quantum dot, which converts the light of the first color (for example, blue) emitted from the light emitting element LD into infrared light. According to an embodiment, the second pixel IRPX may further include a light scattering layer including light scattering particles SCT.

A fifth insulating layer INS5 may be disposed on the second bank layer BK2, the color conversion layers CCL1 and CCL2, and the first organic layer OL1.

The fifth insulating layer INS5 may be entirely disposed on the base layer BL to block water or moisture from entering the color conversion layers CCL1 and CCL2 from the outside. The fifth insulating layer INS5 may include an organic material and/or an inorganic material, and may be formed as a single layer or multiple layers.

A light blocking pattern BM may be disposed on the fifth insulating layer INS5. The light blocking pattern BM may overlap the second bank layer BK2 in the third direction DR3. The light blocking pattern BM may be a dam structure that finally defines an area where the color filters CF1 and CF2 are to be supplied.

The light blocking pattern BM may include a light blocking material. For example, the light blocking pattern BM may be a black matrix. The light blocking pattern BM may prevent a light leakage defect in which light is leaked between the first pixel PX and a pixel adjacent thereto (the second pixel IRPX, or the photo sensor PHS), or the light blocking pattern BM may prevent mixing of colors of light emitted from each of adjacent pixels.

The color filters CF1 and CF2 may fill a space surrounded by the light blocking pattern BM. The color filters CF1 and CF2 may selectively transmit light of a specific color. The color filters CF1 and CF2 may be disposed on the color conversion layers CCL1 and CCL2 and may include a color filter material that selectively transmits light of a specific color (or a specific wavelength band) converted in the color conversion layers CCL1 and CCL2.

For example, when the first pixel PX is a red pixel, a first color filter CF1 disposed on the first light emitting element LED may include a red color filter. In addition, when the first pixel PX is a green pixel, the first color filter CF1 may include a green color filter. In addition, when the first pixel PX is a blue pixel, the first color filter CF1 may include a blue color filter. For example, when the second pixel IRPX is an infrared light pixel, a second color filter CF2 disposed on the second light emitting element IRD may be an infrared light filter. When a color filter is not disposed on the light receiving element LRD, the photo sensor PHS does not include a color filter.

A sixth insulating layer INS6 may be entirely disposed and/or formed on the light blocking pattern BM and the color filters CF1 and CF2.

The sixth insulating layer INS6 may be a protective layer covering configurations positioned thereunder, for example, the color filters CF1 and CF2. The sixth insulating layer INS6 may be an insulating layer including an inorganic material or an organic material. According to an embodiment, the sixth insulating layer INS6 may be a planarization layer that alleviates a step difference due to configurations disposed thereunder.

While FIG. 8 illustrates the light blocking pattern BM being disposed between the color filters CF1 and CF2, the disclosure is not limited thereto. For example, instead of the light blocking pattern BM, the color filters CF1 and CF2 may be disposed to overlap each other to block light interference between adjacent pixels.

In addition, the color filters CF1 and CF2 may be formed on the fifth insulating layer INS5 through a continuous process or disposed on the fifth insulating layer INS5 through an adhesive process.

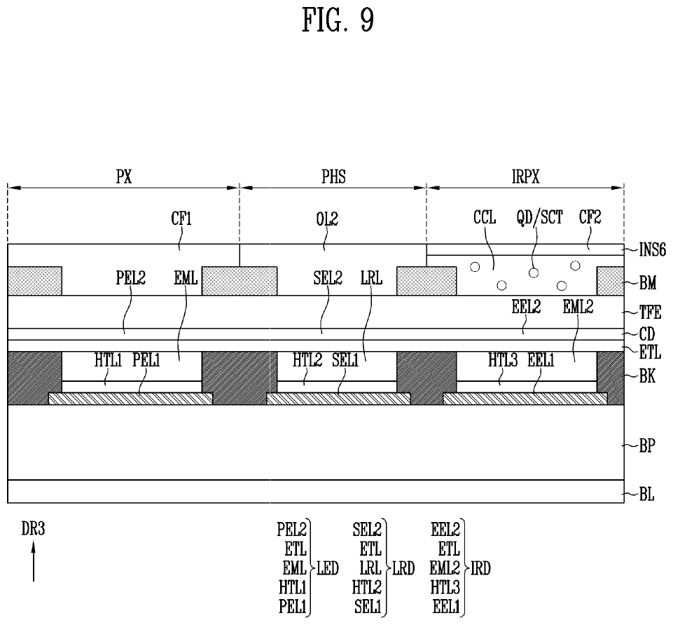

FIG. 9 is a cross-sectional view illustrating an embodiment of the display area of FIG. 4. In describing the embodiment of FIG. 9, a detailed description of a configuration similar to or identical to that of the previously described embodiment is omitted.

Referring to FIGS. 1 to 5 and 7 to 9, the first pixel PX may further include a first color filter CF1, and the second pixel IRPX may include a color conversion layer CCL and a second color CF2.

A light blocking pattern BM may be disposed on the encapsulation layer TFE. The light blocking pattern BM may be disposed between adjacent configurations among the first pixel PX, the photo sensor PHS, and the second pixel IRPX.

The color conversion layer CCL may be disposed in an area surrounded by the light blocking pattern BM. The color conversion layer CCL may be disposed on the second light emitting element IRD. The color conversion layer CCL is not disposed on the first pixel PX and the photo sensor PHS. The color conversion layer CCL may include color conversion particles QDs (or wavelength conversion particles) corresponding to a specific color or a specific wavelength band. For example, when the second pixel IRPX is an infrared light pixel, the color conversion layer CCL of the second pixel IRPX may include color conversion particles QD of an infrared light quantum dot, which converts the light of the first color (for example, blue) emitted from the light emitting element LD into infrared light. According to an embodiment, the second pixel IRPX may further include a light scattering layer including light scattering particles SCT.

The second color filter CF2 may be disposed on the color conversion layer CCL. For example, the second color filter CF2 may be an infrared light filter.

The first color filter CF1 may fill a space surrounded by the light blocking pattern BM and may be disposed on the light emitting element LD. For example, the first color filter CF1 may be a red color filter, a green color filter, or a blue color filter.

A second organic layer OL2 may be disposed in an area surrounded by the light blocking pattern BM and may be disposed on the photo sensor PHS. The second organic layer OL2 may include an organic material.

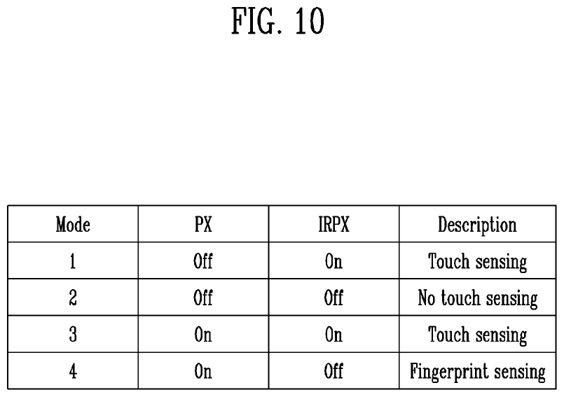

FIG. 10 is a diagram illustrating an operation for each mode of the first pixel and the second pixel of FIG. 5.

Referring to FIGS. 1, 2, 5, 6, and 10, in a first mode, the first pixel PX does not emit light (for example, Off), and the second pixel IRPX emits light (for example, On). In this case, the photo sensor PHS may receive infrared light emitted from the second pixel IRPX and reflected by an object. The sensor driver 220 (or processor) may sense proximity, touch, or the like of the object based on a sensing signal (that is, a sensing signal corresponding to the infrared light) received from the photo sensor PHS (that is, touch sensing).

For example, in the first mode, a display function of the display device may be maintained in an off state (or an inactive state), and a sensing function (for example, a touch sensing function) of the display device may be maintained in an on state (or an active state). The second pixel IRPX may emit light, but infrared light emitted from the second pixel IRPX may not be recognized by the user. When the proximity, the touch, or the like of the object is sensed in the first mode, the display function of the display device may be activated (for example, switching to a third mode or a fourth mode).

In a second mode, the first pixel PX and the second pixel IRPX do not emit light (for example, Off). Since a light source for the photo sensor PHS does not operate, the photo sensor PHS does not operate and may be maintained in an off state (or an inactive state).

For example, in the second mode, the display function and the sensing function of the display device may be an off state, and when a separate external input (for example, a button input) occurs, the display function and/or the sensing function of the display device may be activated (for example, the third mode or the fourth mode). To reduce power consumption of the display device (for example, power consumption in a standby state), the display device may operate in the first mode or the second mode according to a preset value (for example, user's setting or selection).

In the third mode, the first pixel PX and the second pixel IRPX emit light (for example, On). In this case, the photo sensor PHS may receive visible light emitted from the first pixel PX and reflected by the object, and infrared light emitted from the second pixel IRPX and reflected by the object. The sensor driver 220 (or processor) may sense the proximity, the touch, or the like of the object based on the sensing signal received from the photo sensor PHS (that is, a sensing signal corresponding to the visible light and the infrared light) (that is, touch sensing). That is, in the third mode, the display device may sense the proximity, the touch, or the like while displaying an image.

In the fourth mode, the first pixel PX emits light (for example, On), and the second pixel IRPX does not emit light (for example, Off). For example, when a sensor data signal (or a second data signal) corresponding to black or non-emission is applied to the sensor data line DD of FIG. 5, the second pixel IRPX does not emit light. When the photo sensor PHS is in an on state (or an active state), the photo sensor PHS may receive visible light emitted from the first pixel PX and reflected by the object. The sensor driver 220 (or processor) may sense biometric information, for example, a user's fingerprint, blood pressure, and the like based on a sensing signal (that is, a sensing signal corresponding to the visible light) received from the photo sensor PHS (that is, fingerprint sensing). By using only the visible light of the first pixel PX except for the infrared light of the second pixel IRPX, for example, by excluding the infrared light (or noise caused therefrom) of the second pixel IRPX, accuracy of biometric information sensing may be increased.

For example, when a fingerprint sensing request occurs, the display device may operate in the fourth mode. For example, the display device may display an image of a specific pattern (for example, a white image of a high luminance) on at least a portion of the display device using the first pixel PX, and sense a fingerprint based on only the image.

As described above, the display device may sense the proximity, the touch, or the like of the object by using the second pixel IRPX as a light source. In addition, the display device may sense the user's biometric information using the first pixel PX, and may increase the accuracy of the biometric information sensing by causing the second pixel IRPX not to emit light.

Although the technical spirit of the disclosure has been described in detail in accordance with the above-described embodiments, it should be noted that the above-described embodiments are for the purpose of description and not of limitation. In addition, those skilled in the art may understand that various modifications are possible within the scope of the technical spirit of the disclosure.

The scope of the disclosure is not limited to the details described in the detailed description of the specification. In addition, it is to be construed that all changes or modifications derived from the meaning and scope of the claims and equivalent concepts thereof are included in the scope of the disclosure.

What is claimed is:

1. A display device comprising:
a first pixel configured to emit visible light;
a second pixel configured to emit infrared light; and
a photo sensor configured to receive light,
wherein the first pixel comprises a first light emitting element, an emission control transistor forming a current movement path passing through the first light emitting element, and a first transistor controlling a first driving current flowing through the first light emitting element,
wherein the second pixel comprises a second light emitting element, an eleventh transistor controlling a second driving current flowing through the second light emitting element, and a twelfth transistor electrically connected between a sensor data line and a gate electrode of the eleventh transistor, and
wherein a gate electrode of the emission control transistor and a gate electrode of the twelfth transistor are electrically connected to each other.

2. The display device according to claim 1, wherein the second pixel does not further include a transistor in addition to the eleventh transistor and the twelfth transistor.

3. The display device according to claim 2, wherein a number of transistors included in the second pixel is less than a number of transistors included in the first pixel.

4. The display device according to claim 3, wherein an area of the second pixel is less than or equal to half of an area of the first pixel in a plan view.

5. The display device according to claim 4, wherein a total area occupied by the second pixel and the photo sensor is less than or equal to an area occupied by the first pixel in a plan view.

6. The display device according to claim 2, wherein a number of transistors included in the second pixel is less than a number of transistors included in the photo sensor.

7. The display device according to claim 1, wherein the second pixel and the photo sensor are included in one pixel row extending in a first direction and are arranged along a second direction in a plan view.

8. The display device according to claim 1, further comprising:
a processor configured to sense proximity or touch of an object using light received by the photo sensor in a state in which the second pixel emits light.

9. The display device according to claim 8, wherein the first pixel does not emit the visible light while the second pixel emits the infrared light.

10. The display device according to claim 8, wherein the first pixel emits the visible light while the second pixel emits the infrared light.

11. The display device according to claim 8, wherein the processor senses biometric information using the light received by the photo sensor in a state in which the second pixel does not emit the infrared light and the first pixel emits the visible light, and
wherein the biometric information includes at least one of a fingerprint and blood pressure.

12. The display device according to claim 1, wherein the photo sensor comprises:
a light receiving element;
a first sensor transistor controlling a current flowing through a readout line in response to a voltage of one electrode of the light receiving element; and
a second sensor transistor electrically connected between the first sensor transistor and the readout line.

13. The display device according to claim 12, wherein the first pixel further comprises a second transistor electrically connected to a data line and a gate electrode of the first transistor, and
wherein a gate electrode of the second transistor and a gate electrode of the second sensor transistor are electrically connected to each other.

14. The display device according to claim 12, wherein the first transistor and the eleventh transistor are disposed on a first layer, and
wherein the first light emitting element, the second light emitting element, and the light receiving element are disposed on a second layer.

15. The display device according to claim 12, wherein the first light emitting element emits the visible light, and
wherein the second light emitting element emits the infrared light.

16. The display device according to claim 12, wherein the second light emitting element emits the visible light, and
wherein the second pixel further comprises first color conversion particles disposed on the second light emitting element for converting the visible light into the infrared light.

17. The display device according to claim 16, wherein the first light emitting element and the second light emitting element emit visible light of a first color, and
wherein the first pixel further comprises a second color conversion particle disposed on the first light emitting element for converting the visible light of the first color into visible light of a second color.

18. The display device according to claim 16, wherein the first pixel further comprises a first color filter disposed on the first light emitting element,
wherein the second pixel further comprises a second color filter disposed on the first color conversion particle, and
wherein the photo sensor does not include a color filter.

19. A display device comprising:
first pixels configured to emit visible light;
a second pixel configured to emit infrared light; and
a photo sensor configured to receive light,
wherein an area of the second pixel is less than an area of each of the first pixels in a plan view,
wherein the second pixel and the photo sensor are arranged along a second direction between two first pixels adjacent to each other in a first direction among the first pixels, in a plan view.

20. The display device according to claim 19, wherein a total number of transistors included in the second pixel and the photo sensor is less than a number of transistors included in each of the first pixels.
